(19) United States
(12) Patent Application Publication
(10) Pub. No.: US 2023/0071140 A1
(43) Pub. Date: Mar. 9, 2023

(54) SEMICONDUCTOR DEVICE AND METHOD FOR MANUFACTURING SAME

(71) Applicant: KABUSHIKI KAISHA TOSHIBA, Tokyo (JP)

(72) Inventors: Katsuya SATO, Yokohama (JP); Keiichiro MATSUO, Yokohama (JP)

(73) Assignee: KABUSHIKI KAISHA TOSHIBA, Tokyo (JP)

(21) Appl. No.: 17/653,941

(22) Filed: Mar. 8, 2022

(30) Foreign Application Priority Data
Sep. 7, 2021 (JP) 2021-145633

(51) Int. Cl. H01L 21/66; H01L 23/31; H01L 23/29; H01L 21/56

(52) U.S. Cl. CPC H01L 22/24; H01L 23/3142; H01L 23/293; H01L 21/56; H01L 25/0655

(57) ABSTRACT

A semiconductor device includes a substrate; a semiconductor chip located on the substrate; a sealing resin covering the substrate and the semiconductor chip; and a mottled pattern located at an interface between the sealing resin and at least one of the substrate or the semiconductor chip.

### CROSS-REFERENCE TO RELATED APPLICATION

This application is based upon and claims the benefit of priority from Japanese Patent Application No. 2021-145633, filed on Sep. 7, 2021; the entire contents of which are incorporated herein by reference.

### FIELD

Embodiments described herein relate generally to a semiconductor device and a method for manufacturing the same.

### BACKGROUND

For example, the module interior of a power semiconductor module is sealed with an insulating resin to ensure the insulation properties. The insulation properties cannot be guaranteed and defects may occur when cracks occur in the sealing resin. The existence or absence of cracks in the sealing resin is determined using the naked eye when testing and inspecting, and the determination standard easily differs between workers.

### BRIEF DESCRIPTION OF THE DRAWINGS

FIG. 1 is a schematic cross-sectional view of a semiconductor device of an embodiment;

FIG. 2A is a schematic cross-sectional view of a sample used in an experimental example for verifying effects of the embodiment, and FIG. 2B is an image showing an example of a mottled pattern; and

FIGS. 3A to 3C are images that visualizes a scratch in the above sample.

### DETAILED DESCRIPTION

According to one embodiment, a semiconductor device includes a substrate; a semiconductor chip located on the substrate; a sealing resin covering the substrate and the semiconductor chip; and a mottled pattern located at an interface between the sealing resin and at least one of the substrate or the semiconductor chip.

Embodiments will now be described with reference to the drawings. The same components in the drawings are marked with the same reference numerals.

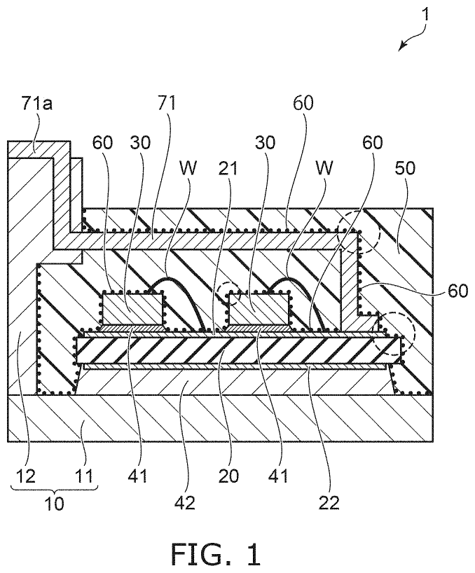

FIG. 1 is a schematic cross-sectional view of a semiconductor device 1 of an embodiment.

The semiconductor device 1 includes a case 10, a substrate 20, a semiconductor chip 30, conductive members 21, 22, and 71, and a sealing resin 50.

The case 10 includes a base 11 and a sidewall portion 12. For example, the base 11 and the sidewall portion 12 are made of insulating resin materials. The substrate 20, the semiconductor chip 30, the conductive members 21, 22, and 71, and the sealing resin 50 are located in a space inside the case 10 that is surrounded with the base 11 and the sidewall portion 12.

The substrate 20 is located on the base 11. The back surface of the substrate 20 is bonded to the upper surface of the base 11 by a bonding member 42. The substrate 20 is, for example, an insulating resin substrate or ceramic substrate. The conductive member 21 is located at the front surface of the substrate 20; and the conductive member 22 is located at the back surface of the substrate 20. The conductive member 21 at the front surface of the substrate 20 functions as wiring that is electrically connected with the semiconductor chip 30. The conductive member 22 at the back surface of the substrate 20 functions as a bonding portion to the base 11.

The semiconductor chip 30 is mounted on the substrate 20. For example, multiple semiconductor chips 30 are mounted on the substrate 20. The back surface of the semiconductor chip 30 is bonded to the substrate 20 by a bonding member 41. An electrode pad is located at the front surface of the semiconductor chip 30; and the electrode pad is electrically connected with the conductive member 21 at the front surface of the substrate 20 by a wire W.

The conductive member 71 that is electrically connected with the conductive member 21 at the front surface of the substrate 20 is located in the case 10. A portion 71a of the conductive member 71 is positioned outside the case 10 and functions as an external connection terminal.

The sealing resin 50 is located inside the case 10 and covers the inner surface of the case 10 (the front surface of the base 11 and the sidewall surface of the sidewall portion 12), the substrate 20, the semiconductor chip 30, the wire W, the conductive members 21 and 22, and the bonding members 41 and 42. The sealing resin 50 also covers the portion of the conductive member 71 positioned inside the case 10. For example, the sealing resin 50 is transmissive to visible light. For example, a silicone resin can be used as the sealing resin 50.

The semiconductor device 1 further includes a mottled pattern 60. The mottled pattern 60 is located at the interface between the sealing resin 50 and the inner surface of the case 10, the interface between the substrate 20 and the sealing resin 50, the interface between the semiconductor chip 30 and the sealing resin 50, and the interface between the sealing resin 50 and the conductive members 21, 22, and 71. It is sufficient for the mottled pattern 60 to be located at an interface between the sealing resin 50 and at least one of the inner surface of the case 10, the substrate 20, the semiconductor chip 30, or the conductive members 21, 22, and 71. The mottled pattern 60 is a pattern of a mixture of different colors and/or shading of the same color, and includes uneven colors and/or luminances. The mottled pattern 60 is made of an electrically insulative material.

As described below according to the semiconductor device 1 of the embodiment, the discrimination of the existence or absence of cracks occurring in the sealing resin 50 is easier by observing the mottled pattern 60 through the sealing resin 50 in an image inspection.

A method for manufacturing the semiconductor device 1 according to the embodiment will now be described.

The substrate 20 is mounted on the base 11 with the bonding member 42 interposed. The semiconductor chip 30 is mounted on the substrate 20 with the bonding member 41 interposed. The electrode pad at the front surface of the semiconductor chip 30 and the conductive member 21 at the front surface of the substrate 20 are connected by the wire W. For example, the plate-shaped conductive member 71 of copper that is connected to the conductive member 21 at the front surface of the substrate 20 is located in the case 10.

The mottled pattern 60 is formed on at least one of the inner surface of the case 10, the substrate 20, the semiconductor chip 30, or the conductive members 21, 22, and 71. For example, the material of the mottled pattern 60 is coated by being dispersed inside the case 10 together with compressed air and/or nitrogen. Or, the material of the mottled pattern 60 is dispersed inside the case 10 and coated by electrostatic force. For example, the mottled pattern 60 covers the inner surface of the case 10, the substrate 20, the semiconductor chip 30, and the conductive members 21, 22, and 71.

The sealing resin 50 that covers the inner surface of the case 10 and the members inside the case 10 (the substrate 20, the semiconductor chip 30, the conductive members 21, 22, and 71, the wire W, the bonding members 41 and 42, and the mottled pattern 60) is formed inside the case 10. For example, the sealing resin 50 is supplied to the interior of the case 10 in a gel or liquid state and subsequently cured by heating, etc.

The sealing resin 50 is formed after forming the mottled pattern 60. Therefore, the mottled pattern 60 is positioned at the interface between the sealing resin 50 and the inner surface of the case 10 and/or the interface between the sealing resin 50 and the members inside the case 10 (the substrate 20, the semiconductor chip 30, the conductive members 21, 22, and 71, the wire W, and the bonding members 41 and 42) but is not positioned at the front surface of the sealing resin 50 or inside the sealing resin 50.

For example, a camera is used to image the mottled pattern 60 through the sealing resin 50 from outside the case 10; and multiple images of the mottled pattern 60 are acquired through the sealing resin 50. For example, the image of the mottled pattern 60 is acquired through the sealing resin 50 when shipping, before testing, when inspecting, after testing, etc.

Then, a correlation value between the acquired multiple images of the mottled pattern 60 is calculated. The correlation value is, for example, a correlation value of the luminance distribution of the mottled pattern 60. When a crack occurs in the sealing resin 50, the reflected light from the mottled pattern 60 positioned under the crack is scattered by the crack; and the image information (e.g., the luminance) of the mottled pattern 60 is different from where there is no crack. For example, the correlation value of the luminance distribution is calculated between two images by comparing an image of the mottled pattern 60 through the sealing resin 50 acquired before the crack occurred in the sealing resin 50 and an image of the mottled pattern 60 through the sealing resin 50 acquired after the crack occurred in the sealing resin 50; and image processing is used to display the acquired images to overlap. For example, the pixels for which the luminance is different between the compared images are given a different color from the pixels for which the luminance is the same. The crack that occurred in the sealing resin 50 becomes visible thereby; and an objective evaluation of the existence or absence of cracks that is not dependent on the worker is possible.

An experimental example for verifying the effects of the embodiment will now be described.

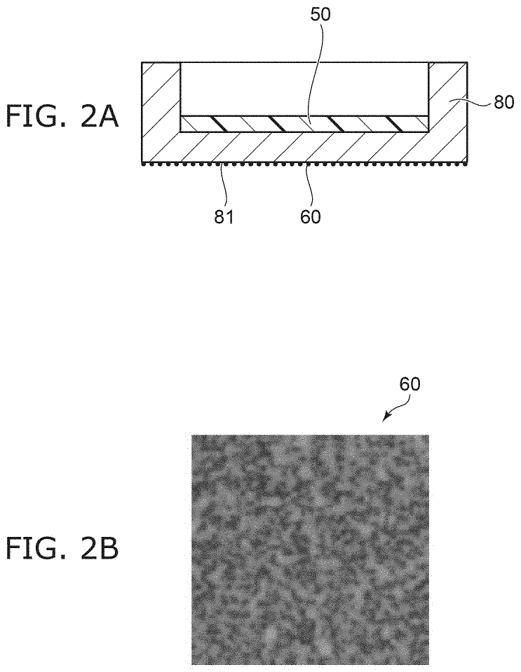

As shown in FIG. 2A, a white coating was spray-coated onto a back surface 81 of a glass petri dish 80; and a black coating was then spray-coated. Thereby, the mottled pattern 60 shown in FIG. 2B was formed on the back surface 81 of the glass petri dish 80.

After forming the mottled pattern 60, a gel silicone resin that was transmissive to visible light was supplied to the interior of the petri dish 80 as the sealing resin 50. The mass of the gel silicone resin supplied to the interior of the petri dish 80 was 7.7 g. Subsequently, the sealing resin (the silicone resin) 50 was cured by heating with a hotplate. The heating temperature was 80° C.; and the heating time was 1.5 hours.

After curing, three line-shaped scratches were made in the front surface of the sealing resin 50 by lightly scratching the front surface of the sealing resin 50 with a scriber. The image (a reference image) of the mottled pattern 60 through the sealing resin 50 before making the scratches, the image of the mottled pattern 60 through the sealing resin 50 after making the first scratch, the image of the mottled pattern 60 through the sealing resin 50 after making the second scratch, and the image of the mottled pattern 60 through the sealing resin 50 after making the third scratch were acquired by imaging with a camera. Then, a correlation value of the luminance distribution of the reference image before making the scratches and the images after making the scratches was calculated, and image processing was used to make the luminance distribution difference from the reference image visible in the images after making the scratches.

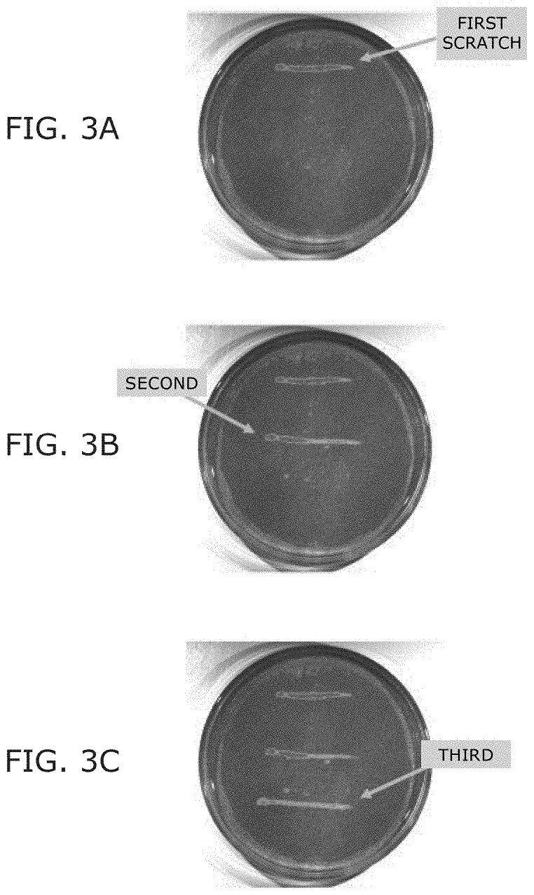

FIG. 3A is an image in which the luminance distribution difference from the reference image is made visible for the image of the mottled pattern 60 through the sealing resin 50 after making the first scratch.

FIG. 3B is an image in which the luminance distribution difference from the reference image is made visible for the image of the mottled pattern 60 through the sealing resin 50 after making the second scratch.

FIG. 3C is an image in which the luminance distribution difference from the reference image is made visible for the image of the mottled pattern 60 through the sealing resin 50 after making the third scratch.

It can be confirmed in the images of FIGS. 3A to 3C that although the luminance of the mottled pattern does not appear to be different from the reference image in regions without scratches, the luminances of the mottled patterns in the regions of the sealing resin where scratches were made are different from the luminances where there are no scratches. For example, the discrimination of the existence or absence of cracks occurring in the sealing resin 50 is made easier by using a different color for the portions having a different luminance when displaying such portions in the image.

Compared to a uniform pattern of the luminance and/or the chromaticity, the mottled pattern that is observed through the sealing resin provides a large change of the image information (e.g., the luminance) due to the existence or absence of cracks occurring in the sealing resin; and the cracks can be easily made visible based on the change amount. For example, one type of material that has a different color from at least one of the case 10, the substrate 20, the semiconductor chip 30, or the conductive members 21, 22, and 71 can be used as the mottled pattern.

Or, a material made of two types of materials having mutually-different colors can be used as the mottled pattern. For example, one of the two types of materials is black; and the other of the two types of materials is white. For example, carbon black can be used as the black material; and titanium oxide can be used as the white material. For example, carbon black and titanium oxide can be coated inside the case 10 by dissolving in a solution such as water, etc. A uniform mottled pattern of gray in which black and white are mixed is easily made by mixing the black material and the white material and coating the mixture inside the case 10. Accordingly, for example, the mottled pattern is formed by coating the white material inside the case 10 after coating the black material inside the case 10. Or, the mottled pattern is formed by coating the black material inside the case 10 after coating the white material inside the case 10.

It is favorable for the size (or the diameter) of the unit region used to configure the mottled pattern (the region that can be discriminated from the adjacent regions in color and/or luminance) to be greater than the pixel resolution of the camera and less than the width of cracks occurring in the sealing resin (the width in a direction orthogonal to the extension direction of the crack). For example, it is favorable for the size (or the diameter) of the unit region used to configure the mottled pattern to be not less than 1/2000 and not more than 20/2000 of the size of the sealing region of the sealing resin 50 inside the case 10. For example, when the size of the sealing region of the sealing resin 50 inside the case 10 is 100 mm square, it is favorable for the size (or the diameter) of the unit region used to configure the mottled pattern to be not less than 0.05 mm and not more than 1.00 mm.

The wavelength for observing the mottled pattern through the sealing resin is not limited to visible light. For example, an image of the mottled pattern through the sealing resin may be acquired using X-rays.

The mottled pattern 60 described above is applicable even when the case 10 is not included.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a substrate;
a semiconductor chip located on the substrate;
a sealing resin covering the substrate and the semiconductor chip; and
a mottled pattern located at an interface between the sealing resin and at least one of the substrate or the semiconductor chip.

2. The device according to claim 1, wherein
the mottled pattern is made of one type of material having a different color from the at least one of the substrate or the semiconductor chip.

3. The device according to claim 1, wherein
the mottled pattern is made of two types of materials having mutually-different colors.

4. The device according to claim 3, wherein
one of the two types of materials is black, and
the other of the two types of materials is white.

5. The device according to claim 1, wherein
the sealing resin is transmissive to visible light.

6. The device according to claim 1, further comprising:
a case in which the substrate is located; and
a conductive member located on the substrate, the conductive member being electrically connected with the semiconductor chip,
the sealing resin being located inside the case and covering the conductive member, the semiconductor chip, the substrate, and an inner surface of the case,
the mottled pattern being located also at an interface between the sealing resin and the inner surface of the case, and at an interface between the conductive member and the sealing resin.

7. A method for manufacturing a semiconductor device, the method comprising:
placing a substrate and a semiconductor chip inside a case, the semiconductor chip being located on the substrate;
forming a mottled pattern on at least one of the semiconductor chip, the substrate, or an inner surface of the case;
forming a sealing resin inside the case, so that the sealing resin covers the mottled pattern, the semiconductor chip, the substrate, and the inner surface of the case;
acquiring a plurality of images of the mottled pattern through the sealing resin; and
calculating a correlation value between the plurality of images of the mottled pattern.

8. The method according to claim 7, wherein
the correlation value is a correlation value of a luminance distribution of the mottled pattern.

9. The method according to claim 7, wherein
the mottled pattern is made of one type of material having a different color from the at least one of the substrate or the semiconductor chip.

10. The method according to claim 7, wherein
the mottled pattern is made of two types of materials having mutually-different colors.

11. The method according to claim 10, wherein
one of the two types of materials is black, and
the other of the two types of materials is white.

12. The method according to claim 7, wherein
the sealing resin is transmissive to visible light.
